(19) United States
(12) Patent Application Publication
(10) Pub. No.: US 2010/0001762 A1
(43) Pub. Date: Jan. 7, 2010

(54) DOMAIN CROSSING CIRCUIT AND METHOD

(75) Inventor: Kyung-Whan KIM, Gyeonggi-do (KR)

Correspondence Address: IP & T Law Firm PLC, 7700 Little River Turnpike, Suite 207, Fairfax, VA, 22003, US

(73) Assignee: HYNIX SEMICONDUCTOR, INC., Gyeonggi-do (KR)

(21) Appl. No.: 12/325,381

(22) Filed: Dec. 1, 2008

(30) Foreign Application Priority Data
Jul. 3, 2008 (KR) 10-2008-0064397

(51) Int. Cl. H03K 19/00

(52) U.S. Cl. 326/93; 326/30

(57) ABSTRACT

A domain crossing circuit for reducing current consumption includes an internal counter to count an internal clock in response to the release of a reset signal, outputting an internal code, a replica delay unit to delay the reset signal as much as a timing difference between the internal clock and an external clock, outputting a delayed reset signal, an external counter to count the external clock in response to the release of the delayed reset signal outputted from the replica delay unit, outputting an external code, and an internal signal generation unit to convert an external signal to an internal signal using the internal code and the external code.

### CROSS-REFERENCE TO RELATED APPLICATION

The present invention claims priority of Korean patent application number 10-2008-0064397, filed on Jul. 3, 2008, which is incorporated by reference in its entirety.

### BACKGROUND OF THE INVENTION

The present invention relates to a domain crossing circuit, and more particularly, to a technology for reducing the current consumption of a domain crossing circuit.

In general, a semiconductor memory device such as a double data rate synchronous DRAM (DDR SRAM) receives various commands synchronized with an external clock, operates in synchronization with an internal clock, and thus outputs data.

That is, although the commands are inputted to the semiconductor memory device from the external in a state of being synchronized with the external clock, the semiconductor memory device performs internal operations in a state of being synchronized with the internal clock and outputs the data corresponding to the commands in synchronization with the internal clock. Therefore, the semiconductor memory device should include a circuit for converting the commands provided from the external that are synchronized with the external clock to internal commands synchronized with the internal clock. This circuit is referred to as a domain crossing circuit.

Particularly, the semiconductor memory device controls on/off states of a termination operation to terminate an input/output pad in response to a termination command inputted from the external. Therefore, it is required to convert the termination command inputted from the external to an internal termination command.

Moreover, from a double data rate three synchronous DRAM (DDR3 SRAM), it is required to provide a dynamic termination operation according to specifications determined by the joint electron device engineering council (JEDEC). The dynamic termination operation is an operation of setting a resistance value of a termination resistor in a chip to a termination resistance value required in inputting the data if a write command is inputted to the chip without re-setting a mode register set. Therefore, there is a need to convert the write command that is an external command to an internal command.

FIG. 1 illustrates a block diagram of a conventional domain crossing circuit for converting a termination command inputted from the external to an internal command.

Referring to FIG. 1, the domain crossing circuit includes a clock distributer 101, a replica delay unit 102, an internal counter 110, an external counter 120 and an internal signal generation unit 130.

The clock distributer 101 generates a clock DLLCLK2 in response to an internal clock DLLCLK1 supplied through a delay locked loop (DLL). The clock distributer 101 prevents toggling of the clock DLLCLK2 until a rest signal RST is released and outputs the clock DLLCLK2 that is toggled if the reset signal RST is released. That is, the clocks DLLCLK1 and DLLCLK2 are the same internal clock, except that, unlike the internal clock DLLCLK1, the internal clock DLLCLK2 maintains a constant level without being toggled until the reset signal RST is released. The reset signal RST is a signal that is enabled while the domain crossing circuit does not operate and disabled when the domain crossing circuit operates. For instance, the domain crossing circuit is not required to operate in an asynchronous mode. Therefore, at this time, the reset signal RST is enabled; the domain crossing circuit stops its operation; and code values DLLCNT<2:0>, EXTCNT<2:0>, and so on are initialized.

The replica delay unit 102 is a delay circuit where a timing difference between the internal clock DLLCLK2 and an external clock on a semiconductor memory device is modeled, and outputs an external clock EXTCLK after reflecting the timing difference on the inputted internal clock DLLCLK2.

The internal counter 110 is initialized by the reset signal RST and then counts the internal clock DLLCLK2 from a release point of the reset signal RST to output the internal code DLLCNT<2:0>. The internal code DLLCNT<2:0> has an initial value determined according to a column address strobe (CAS) write latency CWL since a starting point of an internal termination operation is changed from an input point of the external command according to the CAS write latency CWL. The JEDEC specification regulates that the CAS write latency CWL has a value limited according to an operational frequency. Therefore, the meaning of the initial value being determined according to the CAS write latency CWL is that the initial value is determined according to the operational frequency.

The external counter 120 is initialized by the reset signal RST and then counts the external clock EXTCLK from the release point of the reset signal RST to output the external code EXTCNT<2:0>. An initial value of the external code EXTCNT<2:0> is set to 0.

The internal signal generation unit 130 includes a normal control unit 132 for generating a normal termination command ODTEN, and a dynamic control unit 131 for generating a dynamic termination command DYNAMIC ODTEN, wherein both of the normal termination command ODTEN and the dynamic termination command DYNAMIC ODTEN are internal commands.

The dynamic control unit 131 generates the dynamic termination command DYNAMIC ODTEN in response to a command WT_STARTP, wherein the command WT_STARTP is a signal generated by a write command and will be described later. The semiconductor memory device starts a dynamic termination operation in response to the activation of the dynamic termination command DYNAMIC ODTEN and stops the dynamic termination operation in response to the inactivation of the dynamic termination command DYNAMIC ODTEN.

The normal control unit 132 generates the normal termination command ODTEN in response to commands ODT_STARTP and ODT_ENDP provided from an external memory controller, wherein the commands ODT_STARTP and ODT_ENDP are signals generated by external commands. The semiconductor memory device determines a starting point and an ending point of the termination operation in response to the normal termination command ODTEN that is an internal command.

FIG. 2 is a view illustrating an operation of the dynamic control unit 131 in FIG. 1.

The internal counter 110 does not operate until the reset signal RST is released and the internal code DLLCNT<2:0> has an initial value of 5 that is determined according to the CAS write latency as described above. Likewise, the external counter 120 does not operate until the reset signal RST is released and the external code EXTCNT<2:0> has an initial value of 0. If the reset signal RST is released, the internal counter 110 and the external counter 120 are activated and the internal clock DLLCLK2 starts to be toggled. Since the external clock EXTCLK is generated by delaying the internal clock DLLCLK2, the external clock EXTCLK is toggled after the internal clock DLLCLK2 is toggled. Therefore, the internal code DLLCNT<2:0> starts to be counted and then the external code EXTCNT<2:0> starts to be counted after a time corresponding to a delay value of the replica delay unit 102 is passed.

If the write command is inputted from externally while the internal code DLLCNT<2:0> and the external code EXTCNT<2:0> are counted, the pulse signal WT_STARTP is enabled in response to the input of the write command. The external code EXTCNT<2:0> at the moment of the pulse signal WT_STARTP being enabled is stored. In FIG. 2, the stored value of the external code EXTCNT<2:0> is 1. When the value of the internal code DLLCNT<2:0> becomes identical to the stored value of the external code EXTCNT<2:0>, i.e., 1, a WT_DLL_STARTBP signal is enabled to a logic low level. The enabled WT_DLL_STARTBP signal enables the dynamic termination command DYNAMIC ODTEN. If the dynamic termination command DYNAMIC ODTEN is enabled, the semiconductor memory device starts the dynamic termination operation.

Hereinafter, the inactivation of the dynamic termination command DYNAMIC ODTEN will be described. In response to the write command, a given value is added to the stored value of the external code EXTCNT<2:0>, i.e., 1, according to a burst length BL. If the burst length BL is 8, eight data are inputted on rising/falling edges of clocks. Therefore, 4 clocks are required to input the eight data and total 6 clocks are required if considering a timing margin before and behind the 4 clocks, which is regulated in the specifications of the JEDEC. If the burst length BL is 4, total 4 clocks including 2 clocks for the data input and 2 clocks for the timing margin are required. This is also regulated in the JEDEC specification.

Therefore, in the case that the burst length BL is 8, a value 6 is added to the stored value of the external code EXTCNT<2:0>, i.e., 1. Since FIG. 2 exemplarily shows the case that the burst length BL is 8, the external code EXTCNT<2:0> has a value 7 that is obtained by adding 6 to 1. Meanwhile, in case that the burst length BL is 4, a value 4 is added to the stored value of the external code EXTCNT<2:0>, i.e., 1. That is, a value corresponding to (BL/2)+2 is added to the external code EXTCNT<2:0>. The value of the external code EXTCNT<2:0> secured by adding the given value to the stored value, e.g., 7 is compared with the value of the internal code DLLCNT<2:0>. When the value of the internal code DLLCNT<2:0> becomes identical to the value of the external code EXTCNT<2:0>, i.e., 7, a WT_DLL_ENDP signal is enabled to a logic low level. The dynamic termination command DYNAMIC ODTEN is disabled in response to the enabled WT_DLL_ENDP signal and thus the dynamic termination operation is ended.

According to the above scheme, the dynamic control unit 131 activates the dynamic termination operation after a certain time is passed from the write command being inputted and inactivates the dynamic termination operation after securing a given margin and a time required in the data input.

FIG. 3 illustrates a view provided to explain the pulse signal WT_STARTP described in FIG. 2.

The pulse signal WT_STARTP is a signal that is enabled in response to the write command. As illustrated in FIG. 3, after an external CAS command CAS corresponding to the write command is inputted and a given time where an additive latency AL is reflected is passed, the pulse signal WT_STARTP is enabled.

In particular, if the external CAS command CAS corresponding to the write command is inputted, a command input buffer receives the external CAS command CAS in a state of being synchronized with a clock CLK. And then, after some delay is caused by an internal circuit, the pulse signal WT_STARTP is enabled. Namely, the pulse signal WT_STARTP is considered as a signal that is generated by receiving the write command from externally and delaying the received command by the some delay. For the reference, a pulse width of the pulse signal WT_STARTP may be properly determined according to a margin.

FIG. 4 is a view illustrating an operation of the normal control unit 132 in FIG. 1.

The internal counter 110 does not operate until the reset signal RST is released and the internal code DLLCNT<2:0> has an initial value of 5 that is determined according to the CAS write latency CWL as described above. Likewise, the external counter 120 does not operate until the reset signal RST is released and the external code EXTCNT<2:0> has an initial value of 0. If the reset signal RST is released, the internal counter 110 and the external counter 120 are activated and the internal clock DLLCLK2 starts to be toggled. Since the external clock EXTCLK is generated by delaying the internal clock DLLCLK2, the external clock EXTCLK is toggled after the internal clock DLLCLK2 is toggled. Therefore, the internal code DLLCNT<2:0> starts to be counted and then the external code EXTCNT<2:0> starts to be counted after a time corresponding to a delay value of the replica delay unit 102 is passed.

During the counting of the internal code DLLCNT<2:0> and the external code EXTCNT<2:0>, the ODT_STARTP signal generated by a command from the external memory controller is enabled. The external code EXTCNT<2:0>at the moment of the ODT_STARTP signal being enabled is stored. In FIG. 4, the stored value of the external code EXTCNT<2:0>is 1. When the value of the internal code DLLCNT<2:0> becomes identical to the stored value of the external code EXTCNT<2:0>, i.e., 1, an ODT_DLL_STARTBP signal is enabled to a logic low level. The enabled ODT_DLL_STARTBP signal enables the normal termination command ODTEN that controls the normal termination operation. If the normal termination command ODTEN is enabled, the semiconductor memory device starts the normal termination operation. The normal termination operation means an existing operation not the dynamic termination operation.

The inactivation of the normal termination command ODTEN is achieved in the same manner as the activation thereof. In response to an ODT_ENDP signal generated by a command from the external memory controller, the external code EXTCNT<2:0> at the moment of the ODT_ENDP signal being enabled is stored. In FIG. 4, the stored value of the external code EXTCNT<2:0>is 6. When the value of the internal code DLLCNT<2:0> becomes identical to the stored value of the external code EXTCNT<2:0>, i.e., 6, an ODT_DLL_ENDBP signal is enabled to a logic low level. The enabled ODT_DLL_ENDBP signal disables the normal termination command ODTEN. If the normal termination command ODTEN is disabled, the semiconductor memory device ends the normal termination operation.

That is, the start and the end of the normal termination operation are basically controlled by the external memory controller.

FIG. 5 illustrates a view provided to explain the ODT_STARTP signal and the ODT_ENDP signal described in FIG. 4.

Both of the ODT_STARTP signal and the ODT_ENDP signal are basically generated by an external ODT command from the external memory controller. The external ODT command is a signal supplied by the external memory controller to satisfy a set-up hold requirement. An ODT_COM signal is generated by synchronizing the external ODT command with a clock and delaying the synchronized external ODT command for a given time with the reflection of the additive latency. The ODT_STARTP signal and the ODT_ENDP signal are enabled as pulse type signals at an enable point and a disable point of the ODT_COM signal, respectively.

Referring back to FIG. 1, the conventional domain crossing circuit employs a scheme of delaying the internal clock to generate the external clock. And, the conventional domain crossing circuit adjusts the count starting points of the internal code and the external code by controlling the internal clock starting to be toggled immediately after the reset signal is released while the external clock starting to be toggled after a time corresponding to the delay value of the replica delay unit is passed from the release of the reset signal.

In a synchronous mode, the external code and the internal code should be continuously counted since it can hardly follow when the external command is inputted and an operation of converting the external command to the internal command should be performed immediately after the external command is inputted. Therefore, in the synchronous mode, the internal clock that always does toggling regardless of the input of the external command is inputted to the replica delay unit.

Whenever the internal clock is toggled, the replica delay unit consumes lots of current, which substantially increases the current consumption in the domain crossing circuit even when the external command is not inputted.

### SUMMARY OF THE INVENTION

Embodiments of the present invention are directed to a domain crossing circuit and method capable of reducing current consumption.

In accordance with an aspect of the present invention, there is provided a domain crossing circuit including: an internal counter configured to count an internal clock in response to a release of a reset signal, and to output an internal code; a replica delay unit configured to delay the reset signal by a timing difference between the internal clock and an external clock, and to output a delayed reset signal; an external counter configured to count the external clock in response to a release of the delayed reset signal, and to output an external code; and an internal signal generation unit configured to convert an external signal to an internal signal using the internal code and the external code.

In accordance with another aspect of the present invention, there is provided a domain crossing circuit including: an internal counter configured to count an internal clock in response to a release of a reset signal, to output an internal code; a replica delay unit configured to delay the reset signal by a timing difference between the internal clock and an external clock, to output a delayed reset signal; an external counter configured to count the external clock in response to a release of the delayed reset signal, to output an external code; and an internal signal generation unit configured to convert an external termination command to an internal termination command using the internal code and the external code.

In accordance with still another aspect of the present invention, there is provided a domain crossing method including: delaying a reset signal by a timing difference between an internal clock and an external clock to output a delayed reset signal; counting the internal clock in response to a release of the reset signal to output an internal code; counting the external clock in response to a release of the delayed reset signal to output an external code; and converting an external signal to an internal signal using the internal code and the external code.

### BRIEF DESCRIPTION OF THE DRAWINGS

FIG. 1 illustrates a block diagram of a conventional domain crossing circuit for converting a termination command inputted from the external to an internal command.

FIG. 2 is a view illustrating an operation of a dynamic control unit in FIG. 1.

FIG. 3 illustrates a view provided to explain a pulse signal WT_STARTP described in FIG. 2.

FIG. 4 is a view illustrating an operation of a normal control unit in FIG. 1.

FIG. 5 illustrates a view provided to explain an ODT_STARTP signal and an ODT_ENDP signal described in FIG. 4.

FIG. 6 illustrates a block diagram of a domain crossing circuit in accordance with an embodiment of the present invention.

FIG. 7 illustrates a block diagram of a replica delay unit in FIG. 6 in accordance with an embodiment of the present invention.

FIG. 8 is a timing diagram illustrating an operation of the domain crossing circuit in accordance with the present invention.

FIG. 9 is a timing diagram illustrating an operation of the domain crossing circuit in an asynchronous mode in accordance with the present invention.

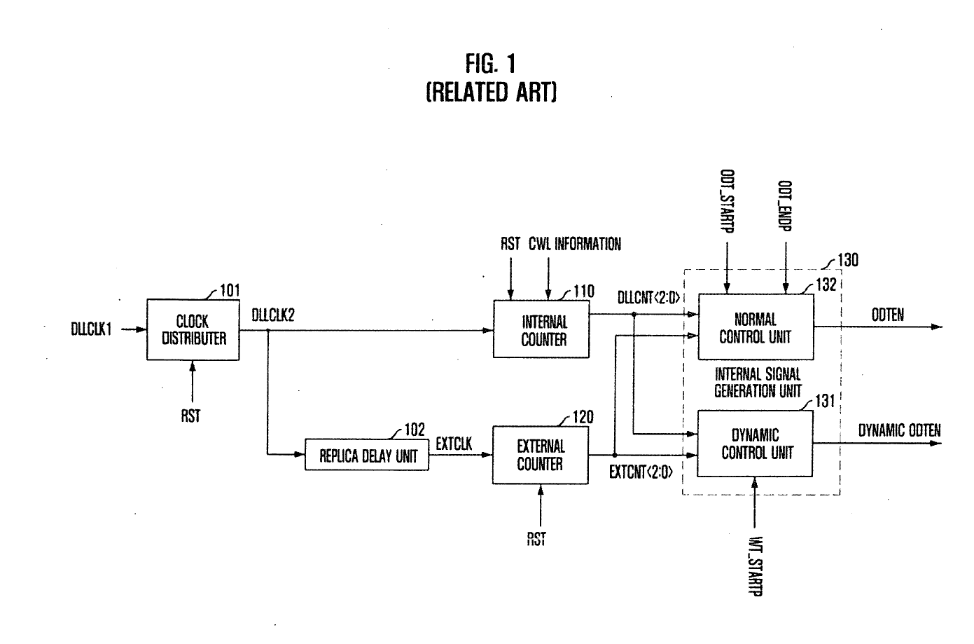

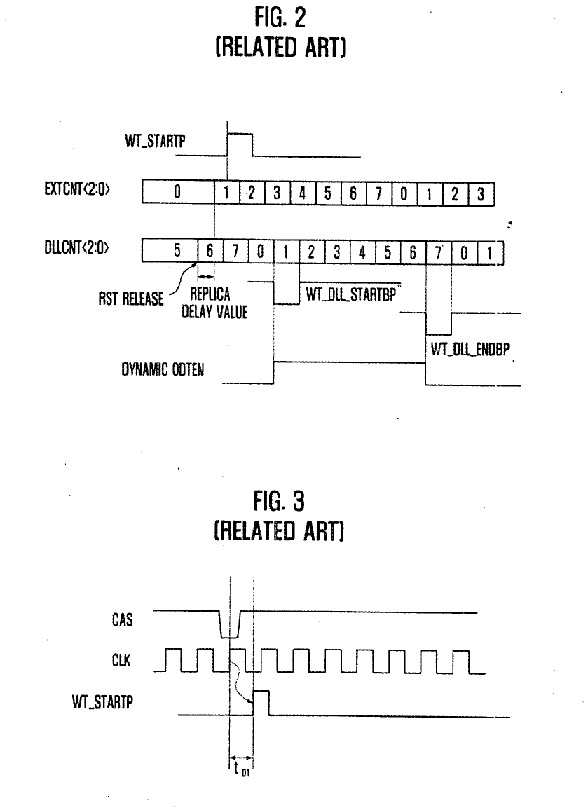

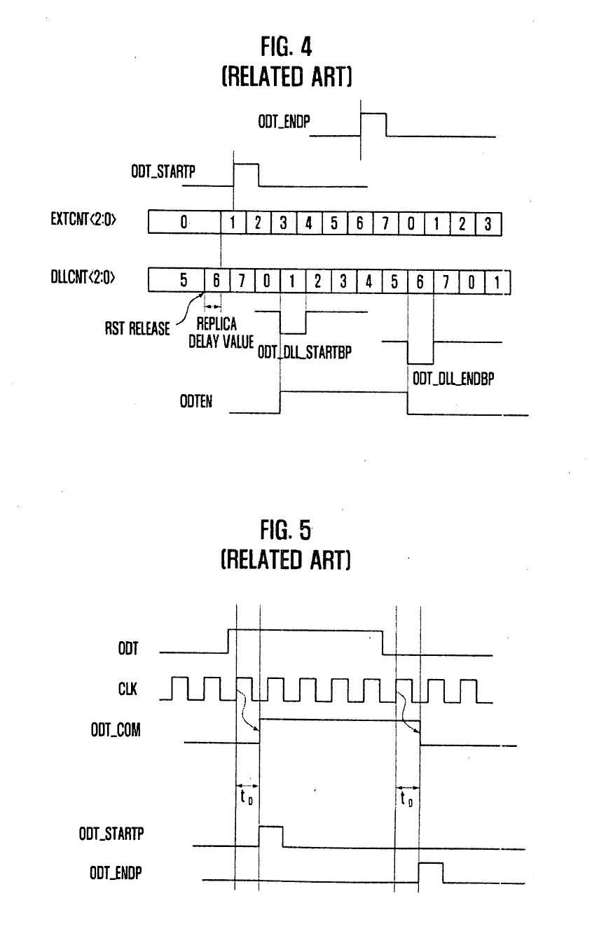

### DESCRIPTION OF SPECIFIC EMBODIMENTS

Other objects and advantages of the present invention can be understood by the following description, and become apparent with reference to the embodiments of the present invention.

FIG. 6 illustrates a block diagram of a domain crossing circuit in accordance with an embodiment of the present invention.

Referring to FIG. 6, the domain crossing circuit includes a clock distributer 601, a replica delay unit 602, an internal counter 610, an external counter 620 and an internal signal generation unit 630.

The clock distributer 601 generates a clock DLLCLK2 in response to an internal clock DLLCLK1. The clock distributer 601 prevents toggling of the clock DLLCLK2 until a rest signal RST is released, and then, outputs the clock DLLCLK2 that is toggled if the reset signal RST is released. That is, the clocks DLLCLK1 and DLLCLK2 are the same internal clock. However, unlike the internal clock DLLCLK1, the internal clock DLLCLK2 maintains a constant level without being toggled until the reset signal RST is released.

As described above, the conventional domain crossing circuit adjusts operating points of the internal counter 110 and the external counter 120 using a difference of points where the internal clock DLLCLK2 and the external clock EXTCLK start to be toggled. Therefore, the conventional domain crossing circuit must include the clock distributer 101 that prevents the toggling of the internal clock DLLCLK2 in a reset operation and allows the internal clock DLLCLK2 to be toggled at the same time of the reset signal RST being released.

However, the inventive domain crossing circuit adjusts operating points of the internal counter 610 and the external counter 620 using a difference of points where the reset signal RST and a delayed reset signal RST_DLY are released. Therefore, the inventive domain crossing circuit may perform its operation without using the clock distributer 601. That is, the internal clock DLLCLK1 may be directly coupled to the internal counter 610. But, if the clock distributer 601 is included in the inventive domain crossing circuit, it is possible to prevent the internal clock DLLCLK2 inputted to the internal counter 610 from being toggled in the reset operation, so that unnecessary current consumption can be reduced. Therefore, it is advantageous to include the clock distributer 601 in terms of the current consumption.

The replica delay unit 602 delays the reset signal RST by a timing difference of the internal clock DLLCLK2 and the external clock EXTCLK. The replica delay unit 602 is a delay circuit where the timing difference between the internal clock DLLCLK2 and an external clock EXTCLK is modeled. Since the replica delay unit 102 of the conventional domain crossing circuit delays the internal clock DLLCLK2 doing toggling, it consumes lots of current. However, since the replica delay unit 602 of the inventive domain crossing circuit delays the reset signal RST, it consumes little current and it has an advantage of its delay value being not affected by power noise although the power noise is coupled thereto. The reset signal RST is enabled in a period where the domain crossing circuit does not operate and disabled in a period where the domain crossing circuit operates. For instance, since the domain crossing circuit needs not to operate in an asynchronous mode where a semiconductor memory device operates regardless of a clock, the reset signal RST is enabled.

The internal counter 610 counts the internal clock DLLCLK2 in response to the release of the reset signal RST, thereby outputting an internal code DLLCNT<2:0>. During the reset signal RST being enabled, the internal counter 610 does not count the internal clock DLLCLK2 and the internal code DLLCNT<2:0> is initialized to an initial value. The internal code DLLCNT<2:0> and an external code EXTCNT<2:0> have a difference of initial values thereof corresponding to a value determined according to a timing parameter of a system where the domain crossing circuit is applied. In the embodiment illustrated in FIG. 6, the circuit is configured to adjust the initial value of the internal code DLLCNT<2:0> according to the timing parameter while fixing the initial value of the external code EXTCNT<2:0>as 0. The timing parameter means latency information, but it can be changed according to which signal is converted in the internal signal generation unit 630. For example, in case that the internal signal generation unit 630 converts an external ODT command to an internal ODT command, a CAS write latency CWL may be the timing parameter. Meanwhile, in case that the internal signal generation unit 630 converts an external read command to an internal read command, a CAS latency CL may be the timing parameter.

The external counter 620 counts the external clock EXTCLK in response to the release of the delayed reset signal RST_DLY that is generated by delaying the reset signal RST using the replica delay unit 602, thereby outputting the external code EXTCNT<2:0>. During the delayed reset signal RST_DLY being enabled, the external counter 620 does not count the external clock EXTCLK and the external code EXTCNT<2:0> is initialized to the initial value. In this embodiment, the external counter 620 starts to count the external clock EXTCLK in response to the release of the delayed reset signal RST_DLY outputted from the replica delay unit 602. Therefore, after the internal counter 610 starts to operate and then a certain time on which the timing difference between the external clock EXTCLK and the internal clock DLLCLK2 is reflected is passed, the external counter 620 starts to operate.

The external clock EXTCLK means a clock that is obtained by converting a clock inputted from the external to a CMOS level through the use of a clock buffer circuit. For instance, a command buffer of the semiconductor memory device receives a command using the clock inputted from the external, and the external clock EXTCLK is the clock that is inputted from the external and used in the command buffer. While the internal clock DLLCLK1 is generated by processing the clock inputted from the external through a delay locked loop (DLL), the external clock EXTCLK is obtained without processing the clock inputted from the external. For that reason, the internal clock DLLCLK1 is different from the external clock EXTCLK.

In the semiconductor memory device, various external clocks are used and the external clock EXTCLK fed to the external counter 620 may use a clock that is not toggled in the asynchronous mode. If a clock doing toggling in the asynchronous mode is used, unnecessary current consumption may be caused by the toggling of the clock.

The internal signal generation unit 630 converts external signals to internal signals using the internal code DLLCNT<2:0> and the external code EXTCNT<2:0> and outputs the internal signals. The external signals mean signals having timing information set on the basis of the external clock provided from the outside of a chip. The internal signals mean signals obtained by converting the external signals with the timing set on the basis of the internal clock.

For instance, if a read command synchronized with the external clock is inputted from the outside of the semiconductor memory device, the semiconductor memory device should perform a read operation. Since, however, the semiconductor memory device operates on the basis of the internal clock, an internal read command is required to internally regulate a starting point of the read operation. Herein, the external read command corresponds to the external signal and the internal read command corresponds to the internal signal.

If the domain crossing circuit converts the external ODT command to the internal ODT command, as described above with reference to the prior art, the internal signal generation unit 630 may be constructed with the normal control unit 132 for generating the normal termination command ODTEN that is an internal command, and the dynamic control unit 131 for generating the dynamic termination command DYNAMIC ODTEN that is an internal command.

The internal signal generation unit 630 may have various configurations according as which external signal is converted to an internal signal by the domain crossing circuit. However, regardless of which external signal to be converted, in general, the internal signal generation unit converts the external signal to the internal signal using a method of enabling the internal signal at a point where the internal code DLLCNT<2:0> becomes identical to the external code EXTCNT<2:0> that is at a point of the external signal being inputted.

Since it is easy for those skilled in the art to properly change the configuration of the internal signal generation unit 630, that converts an external signal command to an internal signal command using the counted internal code DLLCNT<2:0> and the counted external code EXTCNT<2:0>, according to a kind of a signal to be converted in the internal signal generation unit 630, the detailed explanation for the changing of the configuration of the internal signal generation unit 630 may be omitted.

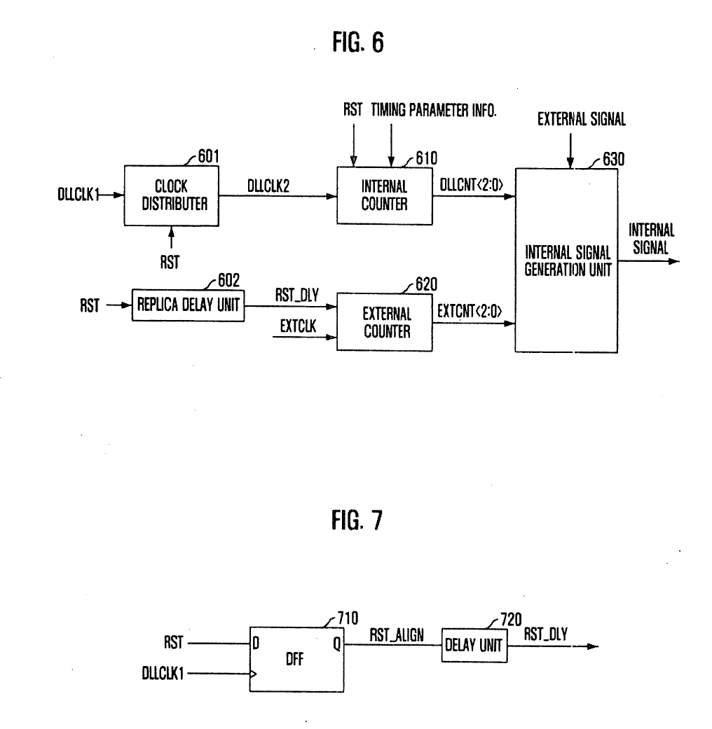

FIG. 7 illustrates a block diagram of the replica delay unit 602 in FIG. 6 in accordance with an embodiment of the present invention.

Referring to FIG. 7, the replica delay unit 602 includes a synchronization unit 710 for synchronizing the reset signal RST with the internal clock DLLCLK1 and outputting a synchronized reset signal RST_ALIGN, and a delay unit 720 for delaying the synchronized reset signal RST_ALIGN outputted from the synchronization unit 710 to output the delayed reset signal RST_DLY.

The replica delay unit 602 is a circuit that reflects the timing difference of the internal clock DLLCLK1 and the external clock EXTCLK. The replica delay unit 602 determines a given time, wherein the counting of the external clock EXTCLK starts after the given time is passed from the starting point of the counting of the internal clock DLLCLK1. The timing difference between the internal cock DLLCLK1 and the external clock EXTCLK can be more precisely reflected by synchronizing the reset signal RST with the internal clock DLLCLK1 using the synchronization unit 710 and delaying the synchronized reset signal RST_ALIGN using the delay unit 720.

The synchronization unit 710 of the replica delay unit 602 may be constructed with a D flip-flop as illustrated in FIG. 7.

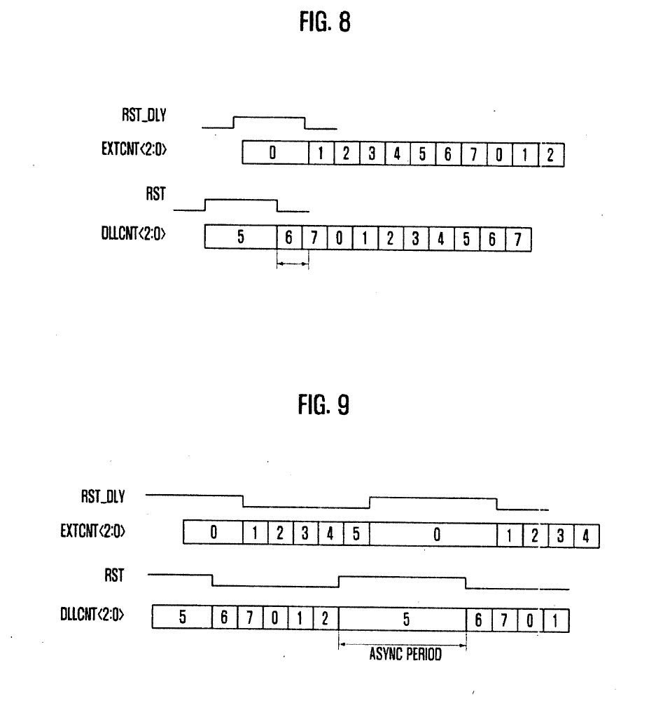

FIG. 8 is a timing diagram illustrating an operation of the domain crossing circuit in accordance with the present invention.

During the reset signal RST and the delayed reset signal RST_DLY being enabled, the internal counter 610 and the external counter 620 do not perform their counting operations and the internal code DLLCNT<2:0> and the external code EXTCNT<2:0> are initialized to initial values of 5 and 0, respectively. The reset signal RST coupled to the internal counter 610 is first disabled and then the counting of the internal code DLLCNT<2:0> starts. Subsequently, the delayed reset signal RST_DLY outputted from the replica delay unit 602 is disabled and the counting of the external code EXTCNT<2:0> starts in response to the disabled delayed reset signal RST_DLY.

Unlike the prior art, the present invention determines operating points of the internal counter 610 and the external counter 620 using a scheme of delaying the reset signal RST through the replica delay unit 602, but the internal code DLLCNT<2:0> and the external code EXTCNT<2:0> are generated identically as in the prior art. Therefore, if using the internal code DLLCNT<2:0> and the external code EXTCNT<2:0>, it is possible to convert the external signals to the internal signals.

FIG. 9 is a timing diagram illustrating an operation of the domain crossing circuit in the asynchronous mode in accordance with the present invention.

During the domain crossing circuit counting the internal code DLLCNT<2:0> and the external code EXTCNT<2:0>, if the semiconductor memory device where the domain crossing circuit is applied enters the asynchronous mode, the reset signal RST and the delayed reset signal RST_DLY are enabled. Therefore, the internal code DLLCNT<2:0> and the external code EXTCNT<2:0> are initialized to initial values 5 and 0, respectively.

Then, if the asynchronous mode is ended and the semiconductor memory device enters a synchronous mode, the reset signal RST and the delayed reset signal RST_DLY are sequentially disabled. As a result, the internal code DLLCNT<2:0> starts to be counted first and then the external code EXTCNT<2:0> starts to be counted.

That is, in accordance with the present invention, it is possible to correctly generate the internal code DLLCNT<2:0> and the external code EXTCNT<2:0> although the semiconductor memory device enters the asynchronous mode and then enters the synchronous mode again during the operation of the internal counter 610 and the external counter 620. As a result, the inventive domain crossing circuit can always correctly convert the external signals to the internal signals in the synchronous mode.

In the conventional domain crossing circuit, since the signal doing toggling is inputted to the replica delay unit, great current consumption is caused. However, in the inventive domain crossing circuit, the reset signal being a level signal is inputted to the replica delay unit. Therefore, the current consumed in the replica delay unit is reduced and thus total current consumption of the domain crossing circuit is finally reduced.

Furthermore, since the operational timing between the internal counter and the external counter is determined by delaying the reset signal that is a level signal not a toggling signal using the replica delay unit, there is an advantage of the delay value of the replica delay unit being not affected by power noise although the power noise occurs.

While the present invention has been described with respect to the specific embodiments, it will be apparent to those skilled in the art that various changes and modifications may be made without departing from the spirit and scope of the invention as defined in the following claims.

What is claimed is:

1. A domain crossing circuit, comprising:
an internal counter configured to count an internal clock in response to a release of a reset signal, and to output an internal code;
a replica delay unit configured to delay the reset signal by a timing difference between the internal clock and an external clock, and to output a delayed reset signal;
an external counter configured to count the external clock in response to a release of the delayed reset signal, and to output an external code; and
an internal signal generation unit configured to convert an external signal to an internal signal using the internal code and the external code.

2. The domain crossing circuit of claim 1, wherein the internal code and the external code have a difference between their initial values, wherein said difference is determined according to a timing parameter of a system in which the domain crossing circuit is applied.

3. The domain crossing circuit of claim 2, wherein the timing parameter includes latency information.

4. The domain crossing circuit of claim 1, wherein the replica delay unit includes:
a synchronization unit configured to synchronize the reset signal with the internal clock, thereby outputting a synchronized reset signal; and
a delay unit configured to delay the synchronized reset signal, to output the delayed reset signal.

5. The domain crossing circuit of claim 1, wherein the internal signal generation unit enables the internal signal when a value of the internal code becomes identical to that of the external code at a point of the external signal being inputted.

6. The domain crossing circuit of claim 1, further comprising a clock distributing unit configured to prevent the internal clock from being inputted to the internal counter until the reset signal is released and to provide the internal clock to the internal counter after the reset signal is released.

7. The domain crossing circuit of claim 1, wherein the external clock is disabled and inputted to the external counter in an asynchronous mode.

8. The domain crossing circuit of claim 1, wherein the reset signal is enabled during a period where the domain crossing circuit is inactivated, wherein said period includes a period of an asynchronous mode.

9. A domain crossing circuit, comprising:
an internal counter configured to count an internal clock in response to a release of a reset signal, to output an internal code;
a replica delay unit configured to delay the reset signal by a timing difference between the internal clock and an external clock, to output a delayed reset signal;
an external counter configured to count the external clock in response to a release of the delayed reset signal, to output an external code; and
an internal signal generation unit configured to convert an external termination command to an internal termination command using the internal code and the external code.

10. The domain crossing circuit of claim 9, wherein the internal code and the external code have a difference between their initial values, wherein said difference is determined according to a column address strobe (CAS) write latency.

11. The domain crossing circuit of claim 9, wherein the replica delay unit includes:
a synchronization unit configured to synchronize the reset signal with the internal clock, to output a synchronized reset signal; and
a delay unit configured to delay the synchronized reset signal, to output the delayed reset signal.

12. The domain crossing circuit of claim 9, wherein the internal signal generation unit converts an external normal termination command to generate an internal normal termination command, and converts an external write command to generate an internal dynamic termination command.

13. The domain crossing circuit of claim 9, further comprising a clock distributing unit configured to prevent the internal clock from being inputted to the internal counter until the reset signal is released, and to provide the internal clock to the internal counter after the reset signal is released.

14. The domain crossing circuit of claim 9, wherein the external clock is disabled and inputted to the external counter in an operation of an asynchronous mode.

15. The domain crossing circuit of claim 9, wherein the reset signal is enabled during a period where the domain crossing circuit is inactivated, wherein said period includes a period of an asynchronous mode.

16. A domain crossing method, comprising:
delaying a reset signal by a timing difference between an internal clock and an external clock to output a delayed reset signal;
counting the internal clock in response to a release of the reset signal to output an internal code;
counting the external clock in response to a release of the delayed reset signal to output an external code; and
converting an external signal to an internal signal using the internal code and the external code.

17. The method of claim 16, wherein the internal code and the external code have a difference between their initial values, wherein said difference is determined according to a timing parameter of a system using the domain crossing method.

18. The method of claim 17, wherein the timing parameter includes latency information.

19. The method of claim 16, wherein converting the external signal to the internal signal includes enabling the internal signal when a value of the internal code becomes identical to that of the external code at a point of the external signal being inputted.
